(19) United States
(12) Patent Application Publication
(10) Pub. No.: US 2004/0055782 A1
(43) Pub. Date: Mar. 25, 2004

(54) Surface-mounting type electronic circuit unit having no melting of solder attaching electric part thereto

(75) Inventor: Yukimasa Yamamoto, Miyagi-ken (JP)

Correspondence Address: Brinks Hofer Gilson & Lione, P.O. Box 10395, Chicago, IL, 60610, US

(73) Assignee: Alps Electric Co., Ltd.

(21) Appl. No.: 10/664,353

(22) Filed: Sep. 17, 2003

(30) Foreign Application Priority Data
Sep. 24, 2002 (JP) UM 2002-006001
Sep. 24, 2002 (JP) UM 2002-006002

(51) Int. Cl. H05K 1/00

(52) U.S. Cl. 174/250

(57) ABSTRACT

The present invention provides a surface-mounting type electronic circuit unit having no melting of solder attaching an electric part thereto and having high reliability. Therefore, the surface-mounting type electronic circuit unit of the present invention has a side electrode arranged on a side face; a circuit substrate having a wiring pattern arranged on an upper face in a state connected to this side electrode; and an electric part connected to the wiring pattern by soldering. A connecting conductor of the wiring pattern connecting the electric part arranged in a position very near the side electrode is formed in a bent state. Therefore, the connecting conductor between the side electrode and the electric part can be lengthened. Accordingly, solder heat due to the soldering of an electrically conductive pattern and the side electrode and the heat of a flux fall on the electric part side, and an influence on the solder attaching the electric part thereto is small so that this solder is not melted and the surface-mounting type electronic circuit unit of high reliability is obtained.

### BACKGROUND OF THE INVENTION

1. Field of the Invention

The present invention relates to a surface-mounting type electronic circuit unit suitably applied to a transmitting-receiving unit, etc.

2. Description of the Related Art

The construction of a conventional surface-mounting type electronic circuit unit will be explained on the basis of FIG. 4. A circuit substrate 51 constructed by a printed board formed by laminating one or plural layers has plural notch portions 51a in its outer circumferential portion.

This circuit substrate 51 has a wiring pattern 52 arranged on its upper face and constructed by sticking copper, and a side electrode 53 arranged on a side face within the notch portion 51a.

The wiring pattern 52 has connecting conductors 52a, 52b connected to the side electrode 53.

An electric part 54 constructed by a semiconductor part, a resistor of a chip type, a capacitor, etc. is soldered to the wiring pattern 52, and is mounted to the circuit substrate 51 by surface mounting, etc.

Thus, the electronic circuit unit is formed in a state in which a predetermined desirable electric circuit is formed in the circuit substrate 51.

When the electric part 54 is mounted to the circuit substrate 51, the connecting conductor 52a connects the electric part 54 arranged in a position very near the side electrode 53, and the connecting conductor 52b connects the electric part 54 arranged in a position far from the side electrode 53.

Both these connecting conductors 52a, 52b are formed by a conductor of a straight line shape (for example, see Patent Literature 1).

The circuit substrate 51 having such a construction is placed on a mother substrate 55. An electrically conductive pattern 56 arranged on the mother substrate 55, and the side electrode 53 are soldered. Thus, an electric circuit formed in the circuit substrate 51 is connected to the mother substrate 55, and the electronic circuit unit attains a state in which the electronic circuit unit is face-mounted to the mother substrate 55.

When the electrically conductive pattern 56 and the side electrode 53 are soldered, heat of the soldering is transmitted to the connecting conductor 52a particularly on the connecting conductor 52a side connecting the electric part 54 arranged in the position very near the side electrode 53. Therefore, high heat has an influence on the solder attaching the electric part 54 thereto so that the high heat melts this solder.

A flux in the soldering is simultaneously moved on the surface of the connecting conductor 52a, and high heat of the flux has an influence on the solder attaching the electric part 54 thereto so that this high heat melts this solder.

[Patent Literature]

Japanese Unexamined Published Patent Application No. 2001-168488

In the conventional surface-mounting type electronic circuit unit, the connecting conductor 52a connecting the electric part 54 arranged in the position very near the side electrode 53 is formed in the shape of a straight line. Therefore, when the side electrode 53 is soldered to the electrically conductive pattern 56 of the mother substrate 55, a problem exists in that the high heat of the solder and the high heat of the flux have influences on the solder attaching the electric part 54 thereto through the short connecting conductor 52a and melt this solder.

### SUMMARY OF THE INVENTION

Therefore, an object of the present invention is to provide a surface-mounting type electronic circuit unit having no melting of the solder attaching the electric part thereto and having high reliability.

As a first solving means for solving the above problems, the present invention is constructed by a surface-mounting type electronic circuit unit comprising a side electrode arranged on a side face; a circuit substrate having a wiring pattern arranged on an upper face in a state connected to this side electrode; and an electric part connected to the wiring pattern by soldering; wherein the wiring pattern has a connecting conductor electrically connecting the side electrode and the electric part, and the connecting conductor connecting the electric part arranged in a position very near the side electrode is formed in a bent state.

Further, as a second solving means, the surface-mounting type electronic circuit unit is constructed such that the connecting conductor is formed in the bent state of a zigzag shape.

Further, as a third solving means for solving the above problems, the present invention is constructed by a surface-mounting type electronic circuit unit comprising a side electrode arranged on a side face; a circuit substrate having a wiring pattern arranged on an upper face in a state connected to this side electrode; and an electric part connected to the wiring pattern by soldering; wherein the wiring pattern has a connecting conductor electrically connecting the side electrode and the electric part, and a silk layer is formed on the connecting conductor connecting the electric part arranged in a position very near the side electrode so as to cross this connecting conductor.

Further, as a fourth solving means, the surface-mounting type electronic circuit unit is constructed such that the connecting conductor is formed in a straight line shape.

Further, as a fifth solving means, the surface-mounting type electronic circuit unit is constructed such that the connecting conductor is formed in a bent state.

Further, as a sixth solving means, the surface-mounting type electronic circuit unit is constructed such that the connecting conductor is formed in the bent state of a zigzag shape.

### BRIEF DESCRIPTION OF THE DRAWINGS

FIG. 1 is an enlarged perspective view showing a first embodiment of a surface-mounting type electronic circuit unit of the present invention.

FIG. 2 is an enlarged perspective view showing a second embodiment of the surface-mounting type electronic circuit unit of the present invention.

FIG. 3 is an enlarged perspective view showing a third embodiment of the surface-mounting type electronic circuit unit of the present invention.

FIG. 4 is an enlarged perspective view showing a conventional surface-mounting type electronic circuit unit.

### DESCRIPTION OF THE PREFERRED EMBODIMENTS

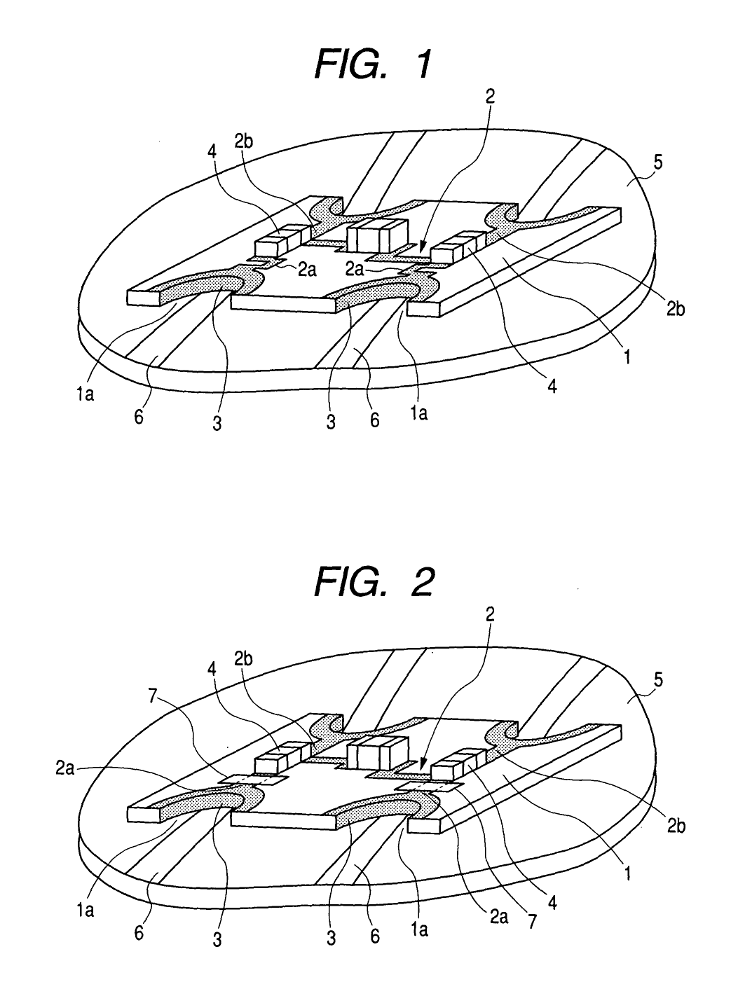

FIG. 1 is an enlarged perspective view showing a first embodiment of a surface-mounting type electronic circuit unit of the present invention. The construction of the surface-mounting type electronic circuit unit of the present invention will be explained on the basis of FIG. 1. A circuit substrate 1 constructed by a printed board formed by laminating one or plural layers has plural notch portions 1a in its outer circumferential portion.

This circuit substrate 1 has a wiring pattern 2 arranged on its upper face and constructed by sticking copper, and also has a side electrode 3 arranged on a side face within the notch portion 1a.

The wiring pattern 2 has connecting conductors 2a, 2b connected to the side electrode 3.

An electric part 4 constructed by a semiconductor part, a resistor of a chip type, a capacitor, etc. is soldered to the wiring pattern 2 so that the electric part 4 is mounted to the circuit substrate 1 by surface mounting, etc.

Thus, the electronic circuit unit is formed in a state in which a predetermined desirable electric circuit is formed in the circuit substrate 1.

When the electric part 4 is mounted to the circuit substrate 1, the connecting conductor 2a connects the electric part 4 arranged in the position very near the side electrode 3, and the connecting conductor 2b connects the electric part 4 arranged in the position far from the side electrode 3.

The connecting conductor 2a connecting the electric part 4 in the position near the side electrode 3 is formed in a bent state between the side electrode 3 and the electric part 4.

This connecting conductor 2a may be also bent in a U-shape, a V-shape, etc., and may be further formed in a zigzag shape.

The connecting conductor 2b connecting the electric part 4 in the position far from the side electrode 3 is formed by a conductor having a straight line shape.

The circuit substrate 1 having such a construction is placed on a mother substrate 5. An electrically conductive pattern 6 arranged on the mother substrate 5, and the side electrode 3 are soldered. Thus, an electric circuit formed in the circuit substrate 1 is connected to the mother substrate 5, and the electronic circuit unit attains a state in which the electronic circuit unit is face-mounted to the mother substrate 5.

When the electrically conductive pattern 6 and the side electrode 3 are soldered, the connecting conductor 2a connecting the electric part 4 arranged in the position very near the side electrode 3 is particularly formed in the bent state. Therefore, it attains a state in which the connecting conductor 2a between the side electrode 3 and the electric part 4 is long.

Therefore, solder heat due to the soldering of the electrically conductive pattern 6 and the side electrode 3, and the heat of a flux fall on the electric part 4 side. Accordingly, an influence on the solder attaching the electric part 4 thereto is small, and it attains a state in which this solder is not melted.

Further, the flow of the flux tending to flow in the shape of a straight line on the surface can be particularly set to be slow by the bent connecting conductor 2a. Therefore, the influence on the solder attaching the electric part 4 thereto due to the flux can be further reduced.

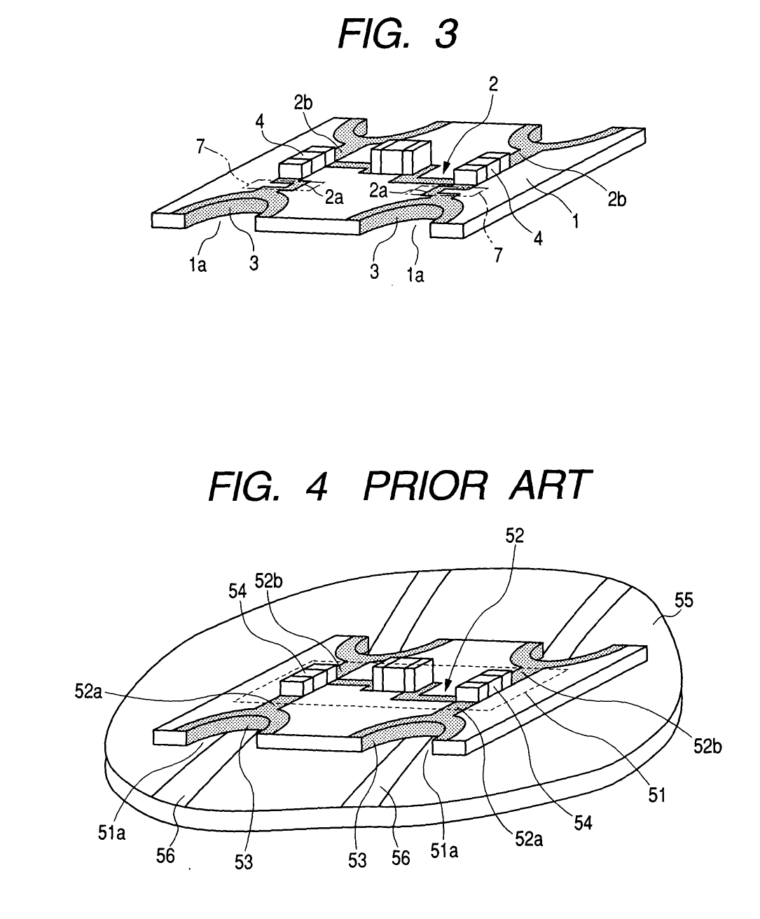

FIG. 2 is an enlarged perspective view showing a second embodiment of the surface-mounting type electronic circuit unit of the present invention. FIG. 3 is an enlarged perspective view showing a third embodiment of the surface-mounting type electronic circuit unit of the present invention. The construction of the second embodiment of the surface-mounting type electronic circuit unit of the present invention will be explained on the basis of FIG. 2. A circuit substrate 1 constructed by a printed board formed by laminating one or plural layers has plural notch portions 1a in its outer circumferential portion.

This circuit substrate 1 has a wiring pattern 2 arranged on its upper face and constructed by sticking copper, and a side electrode 3 arranged on a side face within the notch portion 1a.

The wiring pattern 2 has connecting conductors 2a, 2b connected to the side electrode 3.

An electric part 4 constructed by a semiconductor part, a resistor of a chip type, a capacitor, etc. is soldered to the wiring pattern 2, and is mounted to the circuit substrate 1 by surface mounting, etc.

Thus, the electronic circuit unit is formed in a state in which a predetermined desirable electric circuit is formed in the circuit substrate 1.

When the electric part 4 is mounted to the circuit substrate 1, the connecting conductor 2a connects the electric part 4 arranged in a position very near the side electrode 3. The connecting conductor 2b connects the electric part 4 arranged in a position far from the side electrode 3.

A silk layer 7 constructed by an insulating material is formed by printing on the connecting conductor 2a having a straight line shape and connecting the electric part 4 located in the position near the side electrode 3 such that the silk layer 7 crosses this connecting conductor 2a.

The circuit substrate 1 having such a construction is placed on a mother substrate 5. An electrically conductive pattern 6 arranged on the mother substrate 5, and the side electrode 3 are soldered. Thus, the electric circuit formed in the circuit substrate 1 is connected to the mother substrate 5, and it attains a state in which the electronic circuit unit is face-mounted to the mother substrate 5.

When the electrically conductive pattern 6 and the side electrode 3 are soldered, the silk layer 7 particularly exists on the connecting conductor 2a connecting the electric part 4 arranged in the position very near the side electrode 3. Therefore, solder heat due to the soldering of the electrically conductive pattern 6 and the side electrode 3 is slightly absorbed by the silk layer 7 so that no solder heat melts the solder attaching the electric part 4 thereto.

Further, the flux moved on the surface of the connecting conductor 2a is prevented by the silk layer 7. Accordingly, it is possible to remove the case that the solder attaching the electric part 4 thereto is melted by the flux.

FIG. 3 shows a third embodiment of the surface-mounting type electronic circuit unit of the present invention. In this third embodiment, the connecting conductor 2a connecting the electric part 4 located in the position near the side electrode 3 is formed in a bent state. Further, a silk layer 7 constructed by an insulating material is formed on this bent connecting conductor 2a by printing such that the silk layer 7 crosses this connecting conductor 2a.

Further, the connecting conductor 2b connecting the electric part 4 in the position far from the side electrode 3 is formed by a conductor having a shape straight line shape.

The other constructions are similar to those of the above second embodiment. Accordingly, the same parts as the second embodiment are designated by the same reference numerals, and their explanations are omitted here.

Since the connecting conductor 2a is formed in the bent state, it attains a state in which the connecting conductor 2a between the side electrode 3 and the electric part 4 is long.

Therefore, solder heat due to the soldering of the electrically conductive pattern 6 and the side electrode 3, and the heat of a flux fall on the electric part 4 side by this long connecting conductor 2a. It attains a state in which no solder attaching the electric part 4 thereto is further melted.

Further, the flow of the flux tending to flow in the straight line shape can be set to be particularly slow by the bent connecting conductor 2a. The influence on the solder attaching the electric part 4 thereto due to the flux can be further reduced.

This connecting conductor 2a may be also bent in a U-shape, a V-shape, etc. and may be further formed in a zigzag shape.

The surface-mounting type electronic circuit unit of the present invention comprises a side electrode arranged on a side face; a circuit substrate having a wiring pattern arranged on an upper face in a state connected to this side electrode; and an electric part connected to the wiring pattern by soldering; wherein the wiring pattern has a connecting conductor electrically connecting the side electrode and the electric part, and the connecting conductor connecting the electric part arranged in a position very near the side electrode is formed in a bent state.

Since the connecting conductor connecting the electric part arranged in the position very near the side electrode is formed in the bent state, the connecting conductor between the side electrode and the electric part can be lengthened. Accordingly, solder heat due to the soldering of the electrically conductive pattern and the side electrode and the heat of a flux fall on the electric part side. Therefore, the influence on the solder attaching the electric part thereto is small and this solder is not melted so that the surface-mounting type electronic circuit unit of high reliability can be provided.

Further, since the connecting conductor is formed in the bent state of a zigzag shape, the connecting conductor between the side electrode and the electric part can be further lengthened so that the surface-mounting type electronic circuit unit of higher reliability can be provided.

Further, the surface-mounting type electronic circuit unit of the present invention comprises a side electrode arranged on a side face; a circuit substrate having a wiring pattern arranged on an upper face in a state connected to this side electrode; and an electric part connected to the wiring pattern by soldering; wherein the wiring pattern has a connecting conductor electrically connecting the side electrode and the electric part, and a silk layer is formed on the connecting conductor connecting the electric part arranged in a position very near the side electrode so as to cross this connecting conductor.

Since the silk layer thus exists on the connecting conductor connecting the electric part arranged in the position very near the side electrode, solder heat due to the soldering of the electrically conductive pattern and the side electrode is slightly absorbed by the silk layer so that no solder heat melts the solder attaching the electric part thereto. Further, the flux moved on the surface of the connecting conductor is prevented by the silk layer. Accordingly, it is possible to remove the case that the solder attaching the electric part thereto is melted by the flux. Therefore, the surface-mounting type electronic circuit unit of high reliability can be provided.

Further, since the connecting conductor is formed in the shape of a straight line, the connecting conductor can be shortened and the component of impedance is reduced, which is particularly suitable at high frequencies.

Further, since the connecting conductor is formed in the bent state, the connecting conductor is lengthened and heat can be lowered until the solder attaching the electric part thereto. Accordingly, the surface-mounting type electronic circuit unit of higher reliability can be provided.

Further, since the connecting conductor is formed in the bent state of a zigzag shape, the connecting conductor is further lengthened. Accordingly, heat can be further lowered until the solder attaching the electric part thereto. Therefore, the surface-mounting type electronic circuit unit of higher reliability can be provided.

What is claimed is:

1. A surface-mounting type electronic circuit unit comprising:
a side electrode arranged on a side face;
a circuit substrate having a wiring pattern arranged on an upper face in a state connected to this side electrode; and
an electric part connected to said wiring pattern by soldering;
wherein said wiring pattern has a connecting conductor electrically connecting said side electrode and said electric part, and said connecting conductor connecting said electric part arranged in a position very near said side electrode is formed in a bent state.

2. The surface-mounting type electronic circuit unit according to claim 1, wherein said connecting conductor is formed in the bent state of a zigzag shape.

3. A surface-mounting type electronic circuit unit comprising:
a side electrode arranged on a side face;
a circuit substrate having a wiring pattern arranged on an upper face in a state connected to this side electrode; and
an electric part connected to said wiring pattern by soldering;
wherein said wiring pattern has a connecting conductor electrically connecting said side electrode and said electric part, and a silk layer is formed on said connecting conductor connecting said electric part arranged in a position very near said side electrode so as to cross this connecting conductor.

4. The surface-mounting type electronic circuit unit according to claim 3, wherein said connecting conductor is formed in a straight line shape.

5. The surface-mounting type electronic circuit unit according to claim 3, wherein said connecting conductor is formed in a bent state.

6. The surface-mounting type electronic circuit unit according to claim 5, wherein said connecting conductor is formed in the bent state of a zigzag shape.
